(19) United States
(12) Patent Application Publication
(10) Pub. No.: US 2002/0142531 A1
(43) Pub. Date: Oct. 3, 2002

(54) Dual damascene copper gate and interconnect therefore

(76) Inventors: Sheng Teng Hsu, Camas, WA (US); David R. Evans, Beaverton, OR (US)

Correspondence Address: David C. Ripma, Patent Counsel, Sharp Laboratories of America, Inc., 5750 NW Pacific Rim Boulevard, Camas, WA, 98607, US

(21) Appl. No.: 09/821,210

(22) Filed: Mar. 29, 2001

(51) Int. Cl. H01L 21/338; H01L 21/336; H01L 21/44; H01L 21/3205; H01L 21/4763

(52) U.S. Cl. 438/183; 438/184; 438/586; 438/653; 438/645

(57) ABSTRACT

A method of forming a semiconductor device having a simultaneously formed gate and interconnect therefore, includes preparing a silicon substrate, including isolating active areas thereon; forming an insulating layer in a gate region of an active area; depositing a first barrier metal layer; depositing a gate place-holder layer on the first barrier metal layer; etching the gate place-holder layer and the first barrier metal layer to form a gate stack; building an oxide sidewall about the gate stack; forming a source region and a drain region in the active area; depositing an oxide layer over the structure and etching the oxide layer to form a dual damascene trench to the level of the gate place-holder and to form vias for the source region and drain region; removing the gate place-holder; depositing a second barrier metal layer; depositing copper into the dual damascene trench and the vias; and removing excess copper and all portions of the second barrier metal layer to the level of the last deposited oxide layer.

### RELATED APPLICATIONS

This application is related to U.S. Pat. No. 6,133,106, granted Oct. 17, 2000, to Evans et al., for Fabrication of a planar MOSFET with raised source/drain by chemical mechanical polishing and nitride replacement.

### FIELD OF THE INVENTION

This invention relates to CMOS Integrated circuits, and specifically to the formation, in a single process step, of a metal gate and a metal interconnect therefore.

### BACKGROUND OF THE INVENTION

There are many techniques known in the art for forming a metal gate structure, such as polysilicon replacement gate, nitride replacement gate, or use of a TiN, W, or Mo gate. A metal gate has the advantages of providing high-speed switching, and does not allow boron penetration into the underlying silicon substrate. The known metal gate formations techniques, however, are complex processes, which require additional masking, etching and deposition, resulting in a very high fabrication cost when used in the manufacturing process.

H. Yang et al, A comparison of TiN processes for CVD W/TiNgate electrode on 3 nm gate oxide, IEDM-97, pp459-462, 1997, describes use of TiN as a gate electrode and various techniques for forming such a gate electrode.

A. Chatterjee et al., Sub-100 nm gate length metal gate NMOS transistors fabricated by a replacement gate process, IEDM-97, pp821-824, 1997, describes use of a polysilicon gate place-holder, and subsequent replacement of such place-holder by a metal.

J. C. Hu et al, Feasability of using W/TiNas metal gate for conventional 0.13 μm CMOS technology and beyond, IEDM-97, pp825-828, 1997, describes techniques for using W/TiN as a metal gate.

T. Ushiki et al., Improvement of gate oxide reliability for tantalum-gate MOS devices using xenon plasma sputtering technology, IEEE Transactions on Electronic Devices, Vol. 45, No. 11, pp2349-2354, November 1998, describes advantages of xenon sputtering over argon sputtering.

### SUMMARY OF THE INVENTION

A method of forming a semiconductor device having a simultaneously formed gate and interconnect therefore, includes preparing a silicon substrate, including isolating active areas thereon; forming an insulating layer in a gate region of an active area; depositing a first barrier metal layer; depositing a gate place-holder layer on the first barrier metal layer; etching the gate place-holder layer and the first barrier metal layer to form a gate stack; building an oxide sidewall about the gate stack; forming a source region and a drain region in the active area; depositing an oxide layer over the structure and etching the oxide layer to form a dual damascene trench to the level of the gate place-holder and to form vias for the source region and drain region; removing the gate place-holder; depositing a second barrier metal layer; depositing copper into the dual damascene trench and the vias; and removing excess copper and all portions of the second barrier metal layer to the level of the last deposited oxide layer.

An object of the invention is to provide a low cost metal gate fabrication technology.

Another object of the invention is to provide a method of fabricating a metal gate and a first level interconnect in a single process step.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIGS. 1-5 depict successive steps in forming a dual damascene copper gate and metal interconnect according to the method of the invention.

### DETAILED DESCRIPTION OF THE PREFERRED EMBODIMENTS

The method of the invention provides a technique for the fabrication of a metal gate and an interconnect therefore in a single process step. The method of the invention also provides for simultaneous fabrication of metal interconnects for a source and drain at the same time as forming the gate interconnect. A replacement gate process may complete the front-end process. A nitride replacement is used as an example. This is a low cost process, whose utility will be apparent to those of ordinary skill in the art.

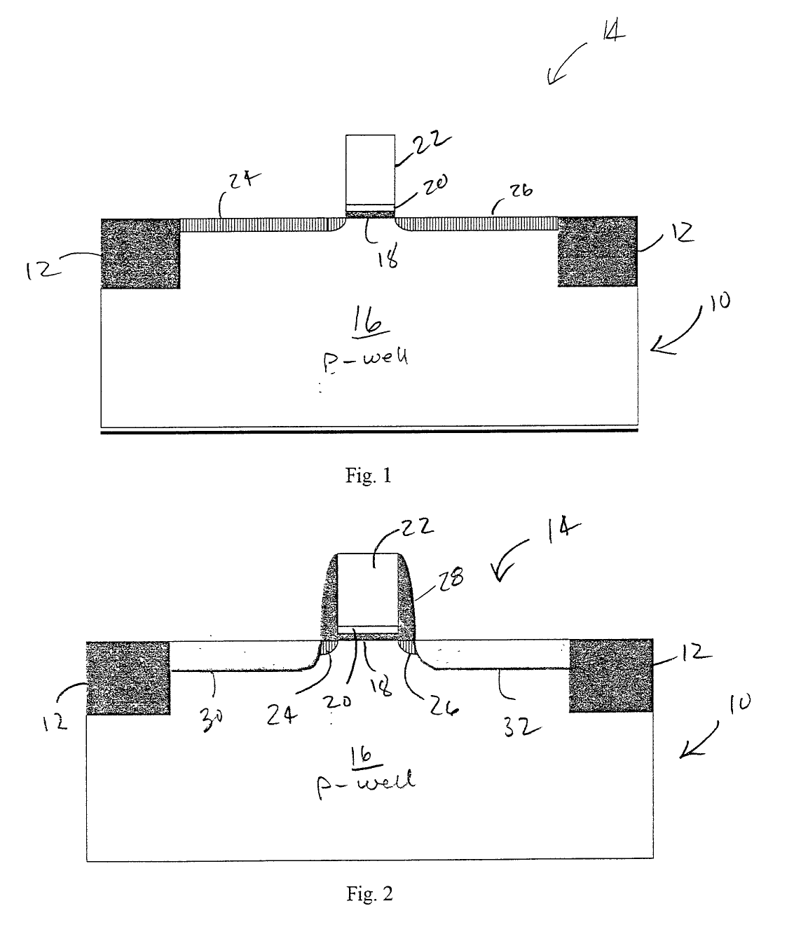

State of the art process are followed for well formation, threshold voltage adjustment, and STI formation. By way of example, and now referring to FIG. 1, a bulk silicon wafer 10 is segmented to provide device isolation by oxide regions 12 and to form device areas, one of which is shown generally at 14. A p-well 16 is formed implantation of boron ions, at a dose of about 5·10¹³ cm⁻² to 5·10¹⁴ cm⁻², and at an energy level of 20 keV to 100 keV. The threshold voltage is adjusted. An insulating layer, which in the preferred embodiment is a gate oxide layer 18, is formed by thermal oxidation. The gate oxide may be replaced with any high-k gate dielectric material, such as HfO₂ or ZrO₂.

A first, or lower, barrier metal layer 20 is deposited to a thickness of between about 5 nm to 20 nm. The barrier metal is the component which determines the flat band voltage, and therefore, controls the threshold voltage of the device. The first barrier metal may not be required if the wet nitride will not degrade the gate insulator reliability. The first barrier metal may be any of TiN, TaN, WN, TiTaN, and TaSiN, as well as other suitable barrier metals.

A nitride layer (Si₃N₄) is deposited by CVD. Photoresist is applied and the nitride etched to form a nitride sacrificial gate 22, also referred to herein as a gate place-holder, having a thickness of between about 100 nm and 300 nm. Barrier metal layer 20 is also etched in this step to form a nitride/barrier metal gate stack. LDD ion implantation, e.g., LDD of arsenic ions, at a dose of 5·10¹³ cm⁻² to 5·10¹⁴ cm⁻², and at an energy level of 10 keV to 30 keV, resulting in the structure of FIG. 1.

An oxide layer is deposited by CVD. This oxide layer is plasma etched to form an oxide side wall 28 about nitride gate 22. An N+ source and drain are formed by ion implantation, for example of arsenic ions at a dose of about 1·10¹⁵ cm⁻² to 5·10¹⁵ cm⁻², and at an energy level of 30 keV to 60 keV, resulting in the structure of FIG. 2. The source and drain, for a PMOS, may also be formed using P+ ions. The forgoing process steps are similar to those disclosed in the above-identified related application.

Additional oxide 34 is deposited by CVD and planarize by CMP to smooth the upper surface of the structure. The thickness of remaining oxide is about the same as the combined height of sacrificial nitride gate 22 and the thickness of first metal layer 20.

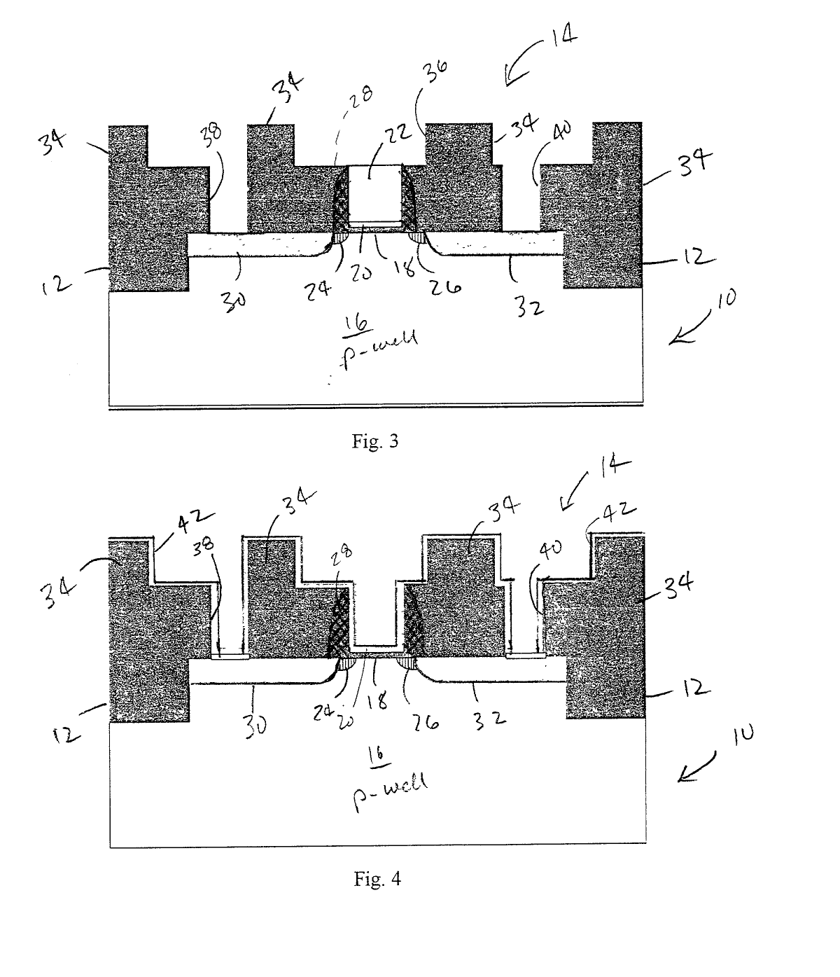

Photoresist is applied prior to etching to form of a dual damascene trench 36 and vias. Complete Dual Damascenes, including the trenches to the first metal layer and the vias, are formed for a source 38 and drain 40 contacts. One trench 36 is provided to the gate interconnect. Forming the gate interconnect trench exposes the upper surface of nitride gate 22, resulting in the structure of FIG. 3.

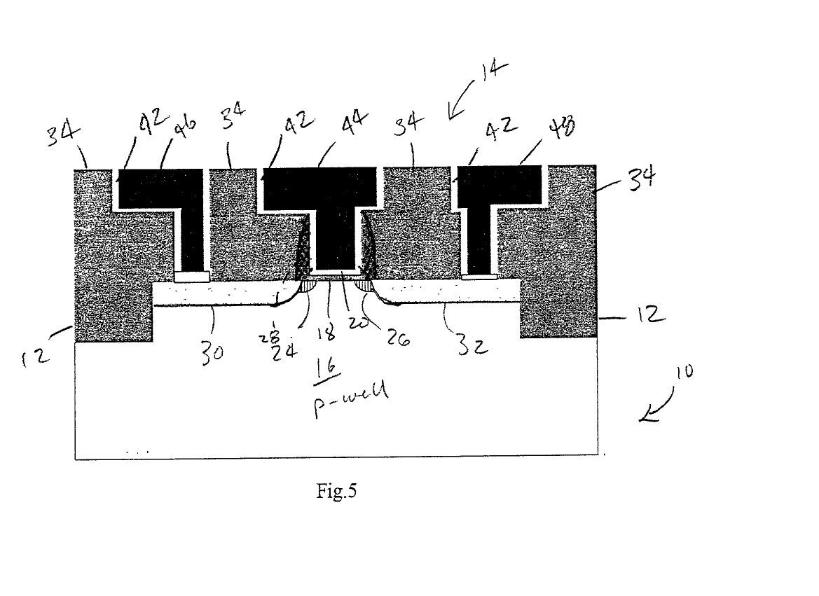

Nitride gate 22 is removed by wet etching, and a second, or upper, barrier metal layer 42 is deposited for copper interconnects, as shown in FIG. 4. The second barrier metal layer may be formed of any of the metals identified for the first barrier metal layer, however, it is preferred that the same metal be used for both the first and second barrier metal layers.

Copper is deposited and polished by CMP to delineate a gate copper interconnect 44, 46, 48, to connect source 30 and drain 32, respectively, and to remove that portion of second barrier metal layer 42 from the top surface of oxide 34, as is shown in FIG. 5.

As the above process demonstrates, the metal gate is formed at the same time as the source/drain interconnect, and saves one metal deposition and one CMP step from the conventional metal gate process. The method of the invention may easily be adapted to the formation of a single Damascene process, wherein the gate electrode and the source and drain via contacts are formed without the requirement of depositing the first interconnect metal.

Thus, a method for forming a dual damascene copper gate and metal interconnect has been disclosed. It will be appreciated that further variations and modifications thereof may be made within the scope of the invention as defined in the appended claims.

We claim:

1. A method of forming a semiconductor device having a simultaneously formed gate and interconnect therefore, comprising:
preparing a silicon substrate, including isolating active areas thereon;
forming an insulating layer in a gate region of an active area;
depositing a first barrier metal layer;
depositing a gate place-holder layer on the first barrier metal layer;
etching the gate place-holder layer and the first barrier metal layer to form a gate stack;
building an oxide sidewall about the gate stack;
forming a source region and a drain region in the active area;
depositing an oxide layer over the structure and etching the oxide layer to form a dual damascene trench to the level of the gate place-holder and to form vias for the source region and drain region;
removing the gate place-holder;
depositing a second barrier metal layer;
depositing copper into the dual damascene trench and the vias; and
removing excess copper and all portions of the second barrier metal layer to the level of the last deposited oxide layer.

2. The method of claim 1 wherein said depositing a gate place-holder includes depositing a thin layer of material taken from the group of materials consisting of silicon nitride and polysilicon.

3. The method of claim 2 wherein said depositing a silicon nitride layer includes depositing the silicon nitride layer to a thickness of between about 100 nm to 300 nm.

4. The method of claim 1 wherein the first and second barrier metals are taken from the group of metals consisting of TiN, TaN, WN, TiTaN, and TaSiN.

5. The method of claim 4 wherein the first barrier metal layer is deposited to a thickness of between about 5 nm and 20 nm.

6. The method of claim 1 wherein said forming an insulating layer includes forming a gate oxide layer.

7. The method of claim 1 wherein said forming an insulating layer includes forming a layer of high-k material taken from the group of materials consisting of HfO₂ and ZrO₂.

8. A method of forming a semiconductor device having a simultaneously formed gate and interconnect therefore, comprising:
preparing a silicon substrate, including isolating active areas thereon;
forming an insulating layer of a gate oxide in a gate region of an active area;
depositing a first barrier metal layer;
depositing a silicon nitride layer on the first barrier metal layer;
etching the silicon nitride layer and the first barrier metal layer to form a gate stack;
building an oxide sidewall about the gate stack;
forming a source region and a drain region in the active area;
depositing an oxide layer over the structure and etching the oxide layer to form a dual damascene trench to the level of the silicon nitride and to form vias for the source region and the drain region;
removing the silicon nitride;
depositing a second barrier metal layer, wherein the first barrier metal and the second barrier metal are taken from the group of metals consisting of TiN, TaN, WN, TiTaN, and TaSiN;
depositing copper into the dual damascene trench and the vias; and
removing excess copper and all portions of the second barrier metal layer to the level of the last deposited oxide layer.

9. The method of claim 8 wherein said depositing a silicon nitride layer includes depositing the silicon nitride layer to a thickness of between about 100 nm to 300 nm.

10. The method of claim 8 wherein the first barrier metal layer is deposited to a thickness of between about 5 nm and 20 nm.

11. A method of forming a semiconductor device having a simultaneously formed gate and interconnect therefore, comprising:
preparing a silicon substrate, including isolating active areas thereon;
forming an insulating layer of a gate oxide in a gate region of an active area;
depositing a gate place-holder layer on the first barrier metal layer, including depositing a thin layer of material taken from the group of materials consisting of silicon nitride and polysilicon;
etching the gate place-holder;
building an oxide sidewall about the gate place-holder;
forming a source region and a drain region in the active area;
depositing an oxide layer over the structure and etching the oxide layer to form a dual damascene trench to the level of the gate place-holder and to form vias for the source region and drain region;
removing the gate place-holder;
depositing an upper barrier metal layer;
depositing copper into the dual damascene trench and the vias; and
removing excess copper and all portions of the upper barrier metal layer to the level of the last deposited oxide layer.

12. The method of claim 11 wherein said depositing a gate place-holder layer includes depositing a silicon nitride layer to a thickness of between about 100 nm to 300 nm.

13. The method of claim 1 1 wherein the upper barrier metal is taken from the group of metals consisting of TiN, TaN, WN, TiTaN, and TaSiN.

14. The method of claim 11 which includes, prior to depositing said gate place-holder layer, depositing a lower barrier metal layer on the gate oxide, and wherein the first barrier metal layer is deposited to a thickness of between about 5 nm and 20 nm, and wherein said etching includes etching the gate place-holder layer and the lower barrier metal layer to form a gate stack..

15. The method of claim 14 wherein the lower barrier metal is taken from the group of metals consisting of TiN, TaN, WN, TiTaN, and TaSiN.
